(19) United States
(12) Patent Application Publication
(10) Pub. No.: US 2022/0140268 A1
(43) Pub. Date: May 5, 2022

(54) METHOD OF MANUFACTURING ALL-SOLUTION-PROCESSED INTERCONNECTION LAYER FOR MULTI-JUNCTION TANDEM ORGANIC SOLAR CELL

(71) Applicants: North Carolina State University, Raleigh, NC (US); NextGen Nano LLC, Raleigh, NC (US)

(72) Inventors: Franky So, Raleigh, NC (US); Carr Hoi Yi Ho, Raleigh, NC (US); Matthew Stone, Raleigh, NC (US)

(21) Appl. No.: 17/577,087

(22) Filed: Jan. 17, 2022

Related U.S. Application Data
(63) Continuation of application No. PCT/US20/42474, filed on Jul. 17, 2020.
(60) Provisional application No. 62/875,274, filed on Jul. 17, 2019.

(51) Int. Cl. H01L 51/42; H01L 51/00

(52) U.S. Cl. CPC H01L 51/4246; H01L 51/0003; H01L 51/0037

(57) ABSTRACT

A method of fabricating an all-solution-processed interconnection layer of a multi-junction tandem organic solar cell includes forming a coating of an aqueous poly(3,4-ethylenedioxythiophene) polystyrene sulfonate dispersion liquid on a sub-cell surface of a multi-junction tandem organic solar cell.

### CROSS-REFERENCE TO RELATED APPLICATION(S)

This application claims the benefit of PCT Patent Application No. PCT/US20/42474, filed on Jul. 17, 2020, which claims the benefit of U.S. Provisional Patent Application No. 62/875,274, filed on Jul. 17, 2019, the entire content of which is incorporated herein by reference.

### TECHNICAL FIELD

The present invention relates generally to the field of photovoltaic power generation, and particularly, to a system and method for producing interconnection layers of a multi-junction photovoltaic cell. The invention also relates to multi-junction tandem organic solar cells comprising a specific interconnection layer.

### BACKGROUND

Organic photovoltaic (OPV) solar cells use organic molecules as the light absorbing material for electricity generation. These molecules have conjugated double bonds, which are capable of transporting electrons. An organic solar cell or plastic solar cell uses organic electronics, a branch of electronics that deals with conductive organic polymers or small organic molecules, for light absorption and charge transport to produce electricity from sunlight by the photovoltaic effect. The general structure of an OPV solar cell consists of a layer of organic semiconductor material sandwiched between two electrical contacts (electrodes), which are deposited on transparent substrates. A transparent conducting oxide, such as indium-tin-oxide (ITO), is used to allow light to pass through the electrode and enter the organic semiconductor layer. In the OPV solar cell, a photon (light) is absorbed by the organic material and an “exciton” is produced. The exciton subsequently separates into an electron and hole, which migrate to their respective opposite electrodes, thereby generating an electrical current.

OPV solar cells have attracted considerable attention in the last decade due to advantages such as flexibility, lightweight, possible semi-transparency, and fast large-area fabrication with low energy consumption. To achieve higher performing OPV solar cells, a tandem structure was developed by stacking two or more sub-cells together. Tandem solar cells can provide an effective way to improve power conversion efficiency of organic solar cell by combining two or more organic solar cells. Each cell has different absorption maximum and width and accordingly provides the ability to use the photon energy more effectively. Whereas single junction organic solar cells suffer from low efficiency due to the limited absorption band of organic materials, in tandem OPV solar cells, the photon utilization efficiency can be improved and the thermal losses can be reduced. With the tandem configurations, the OPV solar cells can extend the optical absorption range and the power conversion efficiency (PCE) has been boosted up to 17%. However, this value is only marginally higher than the record PCE of single OPV device (16.4%).

Accordingly, opportunities exist for improving the power conversion efficiency of tandem OPV solar cells.

### SUMMARY

This summary is provided to introduce in a simplified form concepts that are further described in the following detailed descriptions. This summary is not intended to identify key features or essential features of the claimed subject matter, nor is it to be construed as limiting the scope of the claimed subject matter.

Disclosed herein is a method of fabricating an all-solution-processed interconnection layer of a multi-junction tandem organic solar cell comprises forming a coating of an aqueous poly(3,4-ethylenedioxythiophene) polystyrene sulfonate dispersion liquid on a sub-cell surface of a multi-junction tandem organic solar cell; and, drying the coating to form a hole-transporting sub-layer of an interconnection layer of the multi-junction tandem organic solar cell.

The invention also relates to a multi-junction tandem organic solar cell, comprising: a hole transporting sub-layer of an interconnection layer of the multi-junction tandem organic solar cell comprising poly(3,4-ethylenedioxythiophene) polystyrene sulfonate.

### BRIEF DESCRIPTION OF THE DRAWINGS

FIG. 1A, it is a schematic diagram of a triple junction tandem organic solar cell according to one or more embodiments disclosed herein;

FIG. 1B shows corresponding optical absorption range of the one or more embodiments illustrated in FIG. 1A;

FIG. 2A illustrates a J-V curve of the best double-junction tandem OPV device under AM 1.5G light spectrum;

FIG. 2B illustrates a cross-section scanning electron microscopy of the corresponding device.

FIG. 3 illustrates the data points of two different tandem cells employing various photoactive layers; and

FIG. 4 is a schematic diagram of multi-junction tandem organic solar cell.

### DETAILED DESCRIPTION

The following description and drawings are illustrative and are not to be construed as limiting. Numerous specific details are described to provide a thorough understanding of the disclosure. However, in certain instances, well-known or conventional details are not described in order to avoid obscuring the description. References to “one embodiment” or “an embodiment” in the present disclosure can be, but not necessarily are, references to the same embodiment and such references mean at least one of the embodiments.

Reference in this specification to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not for other embodiments.

The terms used in this specification generally have their ordinary meanings in the art, within the context of the disclosure, and in the specific context where each term is used. Certain terms that are used to describe the disclosure are discussed below, or elsewhere in the specification, to provide additional guidance to the practitioner regarding the description of the disclosure. For convenience, certain terms may be highlighted, for example using italics and/or quotation marks.

The use of highlighting has no influence on the scope and meaning of a term; the scope and meaning of a term is the same, in the same context, whether or not it is highlighted. It will be appreciated that same thing can be said in more than one way.

Consequently, alternative language and synonyms may be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification, including examples of any terms discussed herein, is illustrative only, and is not intended to further limit the scope and meaning of the disclosure or of any exemplified term.

Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, all technical and scientific terms used herein have the same meaning as commonly understood by one of ordinary skill in the art to which this disclosure pertains. In the case of conflict, the present document, including definitions, will control.

In typical organic photovoltaic tandem solar cells (i.e., OPV tandem solar cells), two organic photoactive layers are connected in series by interconnection layer (ICL) to sustain the photocurrent through the entire stack. However, multi-junction organic solar cells having three or more than three active layers face obstacles with regard to the complexity of the fabrication of ICL. Most of the ICLs require one or more of: (1) additives in the precursor solution, (2) an ultra-thin (<5 nm) metal layer, or (3) thermally evaporated metal oxide layers. Whereas multi-junction tandem solar cell should theoretically outperform their double-junction counterparts in terms of larger open circuit voltage, manufacturing multi-junction organic solar cells faces some serious challenges in terms of getting that result of improved PCE values. In other words, the realization of high efficiency and long-term stable tandem devices based on solution-processed ICL remains highly challenging.

Indeed, whereas all-solution-processed ICLs can technically require less production procedures and cost, they can nonetheless be limited by the hydrophobic non-fullerene (NF) based active layer surface. Non-fullerene organic solar cells can potentially benefit from the development of novel non-fullerene acceptors and matching donor semiconductors and can potentially replace traditional expensive fullerene-based OSCs. However, to further increase the power conversion efficiency (PCE) of such devices, it is necessary to offset the narrow absorption of the non-fullerene materials, which is often achieved by adding an additive (>10 wt %) to form a ternary blend. Nevertheless, a high ratio of the third component can often be detrimental to the active layer morphology and can increase the complexity in understanding the device physics toward rationally designed improvements. Accordingly, key challenges exist in developing more-efficient non-fullerene organic solar cells. For example, the device PCE of non-fullerene organic solar cells fabricated by currently available methods yield a PCE of only 10.86% due to the limitations associated with the narrow absorption of the non-fullerene materials. Additionally, with the tandem configurations, the OPV devices can extend the optical absorption range, and the power conversion efficiency (PCE) can be boosted up to 17%. However, this value is just slightly higher than the record PCE of single OPV device (16.4%).

By contrast, embodiments of the presently disclosed subject matter can advantageously result in a PCE value in excess of 17%, for example, up to 25%. Indeed, according to device simulation based on transfer matrix method and drift-diffusion model, improvement in photoactive layers as disclosed herein could lead to a PCE value in excess of 25%. Solution-processed organic photovoltaic (OPV) devices fabricated under the methods as disclosed herein can further allow for the formation of multiple layers in a rapid and continuous manner. Embodiments of the presently disclosed subject matter can overcome the limitations in the prior art by developing a multi-junction organic tandem solar cell featuring a novel ICL, which only requires simple solution casting and low-temperature annealing. Embodiments of the presently disclosed subject matter accordingly advantageously open the potential of multi-junction organic tandem solar cell with large scale and various solution processing methods.

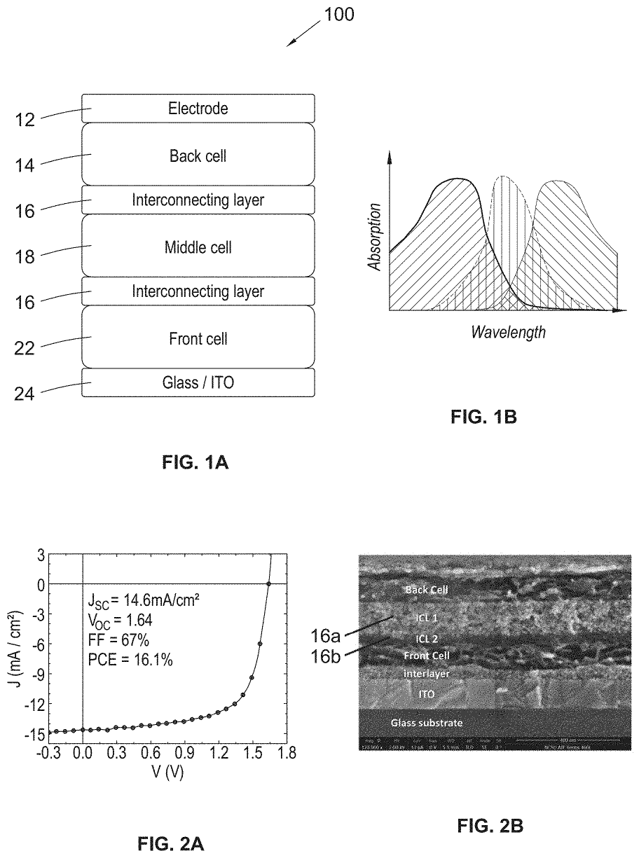

Referring to FIG. 1A, it is a schematic diagram of a triple junction tandem organic solar cell and

FIG. 1B shows their corresponding optical absorption range. FIG. 1A illustrates an all-solution-processed interconnection layer of a multi-junction tandem organic solar cell 100 formed according to one or more embodiments of the presently disclosed subject matter. Solar cell 100 illustrated in FIG. 1A is triple junction tandem organic solar cell comprising a top electrode 10, a back cell 14, an interconnection layer 16, a middle cell 18, the interconnection layer 16 formed between middle cell 18 and a front cell 22, and a transparent conducting glass/indium-tin-oxide layer 24. Interconnection layer 16 can include hole-transporting sub-layer 16b and electron-transporting sub-layer 16a.

As shown in FIG. 2B, interconnection layer 16 can include hole-transporting sub-layer 16b and electron-transporting sub-layer 16a. While hole-transporting sub-layer 16b is shown formed below electron-transporting sub-layer 16a in FIG. 2B, hole-transporting sub-layer 16b can be formed above electron-transporting sub-layer 16a, as required by physical structure and circuitry of the multi-junction tandem organic solar cell 100 being fabricated. Accordingly, in FIG. 2B, layer 16a is the electron-transporting sub-layer 16a and hole-transporting sub-layer 16b is the hole-transporting sub-layer formed of PEDOT:PSS HTL Solar material.

It should be noted that a tandem solar cell can have electron-transporting sub-layer 16a positioned above or below hole-transporting sub-layer 16b as dictated by the physical structure, circuitry, and intended direction of normal electron/hole flow in the multi-junction tandem organic solar cell 100 during operations. FIG. 2B is a mere an example, and the organic solar cell can have other lay-outs, and it is adequate that layer 16 include an electron-transporting sub-layer 16a and a hole-transporting sub-layer 16b irrespective of the positioning of sub-layers 16a and 16b relative to each other.

Embodiments of the presently disclosed subject matter advantageously include constructing an all-solution-processed hole-transporting sub-layer 16b of interconnection layer 16 that is formed of an aqueous PEDOT:PSS dispersion liquid such as that commercially available under the trade name Clevios™ HTL Solar (HTL Solar), and sold by Heraeus Deutschland GmbH & Co. KG of Germany. OPV solar cells including an interconnection layer (ICL) formed in the manner disclosed herein can advantageously extend the optical absorption range and the power conversion efficiency (PCE) to above 17%, for example, above 25%.

PEDOT:PSS stands for poly(3,4-ethylenedioxythiophene) polystyrene sulfonate, which is a transparent conductive polymer consisting of a mixture of two ionomers. In embodiments of the methods of the invention, the poly(3,4-ethylenedioxythiophene) polystyrene sulfonate has a PEDOT:PSS ratio of 1:1 to 1:5, more preferably 1:1.5 to 1:4 and still more preferably 1:2.5. The PEDOT:PSS ratio referred to herein is the stoichiometric ratio of the ionomers.

In embodiments of the methods of the present invention, the aqueous poly(3,4-ethylenedioxythiophene) polystyrene sulfonate dispersion has a viscosity of 8 to 30 mPa·s, more preferably 15 to 30 mPa·s. In embodiments of the methods of the invention, the aqueous poly(3,4-ethylenedioxythiophene) polystyrene sulfonate dispersion is HTL Solar.

HTL Solar is one formulation PEDOT:PSS that includes a unique combination of conductivity, transparency, ductility, and ease of processing. Accordingly, hole-transporting sub-layer 16b of interconnection layer 16 can be formed of a coating of an aqueous poly(3,4-ethylenedioxythiophene) polystyrene sulfonate dispersion liquid (i.e., HTL Solar) according to one or more embodiments of the presently disclosed subject matter. HTL Solar can accordingly be used as the raw-material for forming hole-transporting sub-layer 16b of interconnection layer 16. Hole-transporting sub-layer 16b can benefit from the improved wetting properties of the HTL Solar formulation compared to the other PEDOT:PSS formulations. HTL Solar can have the following specifications:

Resistivity 1−10 Ψ·cm

Solid content 1.0−1.2 wt. % (in water)

Viscosity 8 to 30 multiple millipascal seconds (mPa·s)

PEDOT:PSS ratio 1:2.5

Work Function 4.8−5.0 eV

CAS number 155090-83-8

HTL Solar can have a dried layer conductivity of between 0.1 and 1.0 millisiemens per centimeter (mS/cm). According to one or more embodiments of the presently disclosed subject matter, the dried layer formed of HTL Solar material can operate as the hole-transporting sub-layer 16b of the interconnection layer (ICL) 16, with the corresponding electron-transporting sub-layer 16a fabricated from various inks of electron transporting materials. The all-solution processed ICL can be manufactured by various methods including but not limited to dip coating, spin coating, slot-die coating, doctor blading, and bar coating methods.

Accordingly, a method of fabricating an all-solution-processed interconnection layer 16 of a multi-junction tandem organic solar cell as illustrated in FIG. 1 according to one or more embodiments of the presently disclosed subject matter includes forming a coating of an aqueous poly(3,4-ethylenedioxythiophene) polystyrene sulfonate dispersion liquid on a sub-cell surface of a multi-junction tandem organic solar cell. The method further includes drying the coating to form a hole-transporting sub-layer 16b of an interconnection layer 16 of the multi-junction tandem organic solar cell. Additional hole-transporting sub-layers 16b of the interconnection layer 16 of the multi-junction tandem organic solar cell can be fabricated as required by the multi-junction tandem organic solar cell.

According to one or more embodiments of the presently disclosed subject matter, the coating step is accomplished using one or more of the following technics: dip coating, spin coating, slot-die coating, doctor blade coating, and bar coating.

Dip coating is an industrial coating process which can be used to manufacture bulk products such as coated fabrics and specialized coatings. During dip coating, the substrate is immersed in the coating solution. As it is withdrawn, a liquid layer is entrained on the substrate. The thickness of this entrained solution is determined by the withdrawal speed. The dip-coating process can be separated into five stages:
a. Immersion: The substrate is immersed in the solution of the coating material at a constant speed (preferably jitter-free).
b. Start-up: The substrate has remained inside the solution for a while and is starting to be pulled up.
c. Deposition: The thin layer deposits itself on the substrate while it is pulled up. The withdrawing is carried out at a constant speed to avoid any jitters. The speed determines the thickness of the coating (faster withdrawal gives thicker coating material).
d. Drainage: Excess liquid will drain from the surface.
e. Evaporation: The solvent evaporates from the liquid, forming the thin layer. For volatile solvents, evaporation starts already during the deposition and drainage steps.

Spin coating is a procedure used to deposit uniform thin films onto flat substrates. Usually a small amount of coating material is applied on the center of the substrate, which is either spinning at low speed or not spinning at all. The substrate is then rotated at high speed in order to spread the coating material by centrifugal force. A machine used for spin coating is called a spin coater, or simply spinner. Rotation is continued while the fluid spins off the edges of the substrate, until the desired thickness of the film is achieved. The applied solvent simultaneously evaporates. The higher the angular speed of spinning, the thinner the film. The thickness of the film also depends on the viscosity and concentration of the solution, and the solvent. Spin coating is widely used in microfabrication of functional layers, where it can be used to create uniform thin films with nanoscale thicknesses.

Slot-die coating is a technique where solution is directly coated onto the substrate through a coating “head”. Solution flows through the head at a determined rate and the substrate is moved underneath it. Slot-die coating is a metered coating process. This means that the wet film thickness is determined by the amount of solution placed onto the substrate. All other parameters work to improve the uniformity and stability of the coating. Slot-die coating is classed as a pre-metered coating technique, wherein the final film thickness is dependent upon the rate at which solution passes through the system. This makes the theoretical determination of wet-film thickness easy relative to other methods. Due to the excellent processing window offered by slot-die coating over other roll-to-roll compatible techniques, this method is suitable for use in areas like polymer and perovskite photovoltaic devices, and in organic light-emitting diodes.

Doctor blading or doctor blade coating involves either running a blade over the substrate or moving a substrate underneath the blade. A small gap determines how much solution can get through with the solution effectively spread over the substrate. The final thickness is a fraction of the gap between the substrate and the blade. The final thickness of the wet film will be influenced by the viscoelastic properties of the solution and the speed of coating.

Bar coating—also known as Meyer bar coating—is very similar to doctor blading. During bar coating, an excess of solution is placed on the substrate and it is spread across by a bar. This bar is a spiral film applicator, and is essentially a long cylindrical bar with wire spiraling around it. The gap made between the wire and the substrate determines how much solution is allowed through. This subsequently determines film thickness.

In various embodiments, the method can further include fabricating an electron-transporting sub-layer 16a of the interconnection layer of the multi-junction tandem organic solar cell. The electron-transporting sub-layer can be fabricated before or after the fabrication of the hole-transporting sub-layer of an interconnection layer of the multi-junction tandem organic solar cell, as explained above. In various embodiments, additional hole-transporting sub-layers 16b of the interconnection layer of the multi-junction tandem organic solar cell can be fabricated of the same material depending on the number of interconnection layers 16 needed for the device.

After application of the coating on the sub-cell surface, the coating can be dried using low temperature annealing. Whereas the annealing temperatures can be between 100° C. to 500° C., embodiments of the presently disclosed subject matter can use a low-temperature annealing at a temperature of approximately 300 degrees Celsius or lower to obtain a smooth surface and excellent electronic characteristics to yield highly efficient devices. In some embodiments, the low temperature annealing is undertaken at a low annealing temperature of approximately 200 degrees Celsius or less to achieve a uniform and smooth surface morphology. In some embodiments, the low-temperature anneal can be undertaken at a temperature of approximately 150 degrees Celsius or lower.

For example, in one embodiment, the multi-junction tandem organic solar cell (alternately referred to as the “device”) under fabrication, after the coating has been completed is directly placed on a preheated hot-plate at 200° C. and subjected to a static annealing process for 10 mins-1 hour in air. In another embodiment, the device under fabrication, after the coating has been completed is directly placed into a vacuum oven and evacuated at a pressure of 1×10⁻³ mbar. The temperature of the vacuum oven is then raised to 200° C. over a period of 30 min and then kept for 1 h at the same temperature. In some embodiments, the active layer is further thermal annealed at 150° C. for 5 min to facilitate the self-organization of the coated layer, removal of residual solvent, and assist the polymer contact with the electrode layer.

In embodiments of the methods of the invention, the dried interconnection layer has a thickness of less than 20 nm, e.g. 1 to 20 nm.

In various embodiments, the dried hole-transporting sub-layer of the interconnection layer of the multi-junction tandem organic solar cell has a conductivity of between about 0.1 and about 1.0 millisiemens per centimeter (mS/cm). Conductivity may be measured, according to standard techniques known in the art, using a 4-point probe.

In various embodiments, the multi-junction tandem organic solar cell has a PCE (power conversion efficiency) of at least 13.5%. In some embodiments, the multi-junction tandem organic solar cell has a PCE (power conversion efficiency) of at least 14.7%. In some embodiments, the multi-junction tandem organic solar cell has a PCE (power conversion efficiency) of up to 25% or higher. PCE may be measured, according to standard techniques known in the art, by measuring the current-voltage characteristics of the device under 1-sun condition.

Accordingly, the methods as described herein can result in the fabrication of a multi-junction tandem organic solar cell that includes a hole-transporting sub-layer of an interconnection layer of the multi-junction tandem organic solar cell that is formed by drying a coating of an aqueous poly(3,4-ethylenedioxythiophene) polystyrene sulfonate dispersion liquid formed on a sub-cell surface of a multi-junction tandem organic solar cell.

The invention herein also provides a multi-junction tandem organic solar cell, comprising:

a hole transporting sub-layer of an interconnection layer of the multi-junction tandem organic solar cell comprising poly(3,4-ethylenedioxythiophene) polystyrene sulfonate.

In embodiments of the multi-junction tandem organic solar cell the poly(3,4-ethylenedioxythiophene) polystyrene sulfonate is derived from HTL Solar.

In embodiments of the multi-junction tandem organic solar cell the poly(3,4-ethylenedioxythiophene) polystyrene sulfonate has a PEDOT:PSS ratio of 1:1 to 1:5, more preferably 1:1.5 to 1:4 and still more preferably 1:2.5. The PEDOT:PSS ratio referred to herein is the stoichiometric ratio of the ionomers.

In embodiments of the multi-junction tandem organic solar cell the interconnection layer has a dry thickness of less than 20 nm, e.g. 1-20 nm.

In embodiments the multi-junction tandem organic solar cell further comprises: a first electrode; at least two organic photoactive layers; and a second electrode. Preferably the multi-junction tandem organic solar cell comprises:
a first electrode, preferably comprising ITO-glass;
a first organic photoactive layer;
an interconnection layer comprising a hole-transporting sub-layer comprising poly(3,4-ethylenedioxythiophene) polystyrene sulfonate, preferably as described herein, and an electron-transporting sub-layer;
a second organic photoactive layer; and
a second electrode.

Compared with other widely used interlayers, such as PEDOT:PSS Al 4083, hole-transporting sub-layer 16b formed of HTL Solar material as explained herein can manifest improved wettability on NF active layer surfaces and charge extraction properties. It can further provide a continuous and smooth surface for further device layers construction, as demonstrate in the cross-section scanning electron microscopy image below (FIG. 2). FIG. 2 shows (a) J-V curve of the best double-junction tandem OPV device under AM 1.5G light spectrum, (b)cross-section scanning electron microscopy of the corresponding device.A high-PCE of 14.7% or higher (e.g. 25% or higher) can be achieved with suitable choice of organic photoactive layers with complementary optical absorptions.

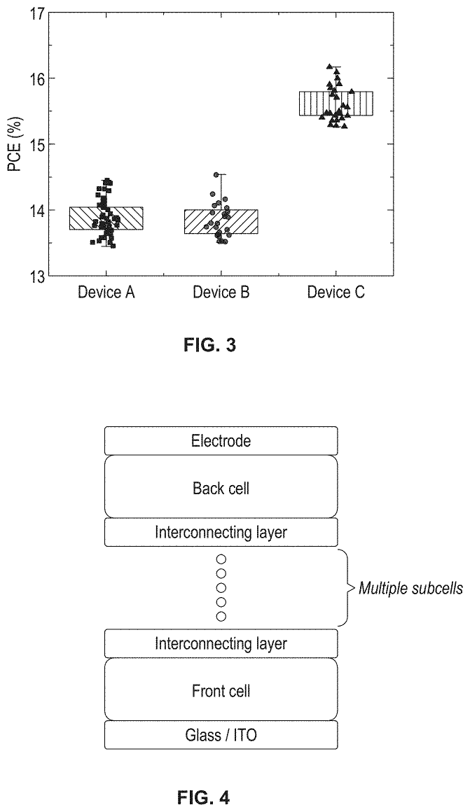

Besides the ability to reach high efficiency, interconnection layer 16 including hole-transporting sub-layer 16b formed by the methods as described herein can demonstrate good compatibility and reproducibility on several photoactive layers. The box chart in FIG. 3 presents the data points of two different tandem cells employing various photoactive layers, with the testing of each device repeated more than 25 times. Testing of the device formed by the methods as described herein (e.g., Device C in FIG. 3) shows good performance (PCE>15%) and small variation within 1%. The box chart in FIG. 3 is demonstrating the reproducibility of tandem cells.

As a person of skill in the art understands, a multi-junction tandem cell includes multiple organic photoactive layers with various bandgaps, the arrangement of bandgap energies of these photoactive materials having a complementary overlap. By the process of device simulation, the rates of photon absorption among the sub-cells can be adjusted and, thereby current-mismatch losses minimized. The simulations make clear that the methods as described herein can advantageously provide for the formation of multiple ICL layers as shown in FIG. 4 in a rapid and continuous manner; the methods as described herein can result in boosting the performance of tandem organic solar cells with higher open-circuit voltage. FIG. 4 is a schematic diagram of multi-junction tandem organic solar cell.

The below references may include information associated with the presently disclosed subject matter:
a. Meng, L., Zhang, Y., Wan, X., Li, C., Zhang, X., Wang, Y., . . . & Yip, H. L. (2018). Organic and solution-processed tandem solar cells with 17.3% efficiency. Science, 361(6407), 1094-1098.
b. Xu, X., Feng, K., Bi, Z., Ma, W., Zhang, G., & Peng, Q. (2019). Single-Junction Polymer Solar Cells with 16.35% Efficiency Enabled by a Platinum (II) Complexation Strategy. Advanced Materials, 1901872.
c. Firdaus, Y., Le Corre, V. M., Khan, J. I., Kan, Z., Laquai, F., Beaujuge, P. M., & Anthopoulos, T. D. (2019). Key Parameters Requirements for Non-Fullerene-Based Organic Solar Cells with Power Conversion Efficiency>20%. Advanced Science, 1802028.

While the methods above have been explained with regard to PEDOT:PSS with the HTL Solar formulation, the methods as described herein can be implemented with other materials as well with suitable modifications made to accommodate the material being used.

Any dimensions expressed or implied in the drawings and these descriptions are provided for exemplary purposes. Thus, not all embodiments within the scope of the drawings and these descriptions are made according to such exemplary dimensions. The drawings are not made necessarily to scale. Thus, not all embodiments within the scope of the drawings and these descriptions are made according to the apparent scale of the drawings with regard to relative dimensions in the drawings. However, for each drawing, at least one embodiment is made according to the apparent relative scale of the drawing.

Unless defined otherwise, all technical and scientific terms used herein have the same meaning as commonly understood to one of ordinary skill in the art to which the presently disclosed subject matter pertains. Although any methods, devices, and materials similar or equivalent to those described herein can be used in the practice or testing of the presently disclosed subject matter, representative methods, devices, and materials are now described.

Following long-standing patent law convention, the terms “a”, “an”, and “the” refer to “one or more” when used in the subject specification, including the claims. Thus, for example, reference to “a device” can include a plurality of such devices, and so forth.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method of fabricating an all-solution-processed interconnection layer of a multi-junction tandem organic solar cell, the method comprising:
forming a coating of an aqueous poly(3,4-ethylenedioxythiophene) polystyrene sulfonate dispersion liquid on a sub-cell surface of a multi-junction tandem organic solar cell;
drying the coating to form a hole-transporting sub-layer of an interconnection layer of the multi-junction tandem organic solar cell.

2. The method of claim 1, wherein said aqueous poly(3,4-ethylenedioxythiophene) polystyrene sulfonate dispersion is HTL Solar.

3. The method of claim 1, wherein said poly(3,4-ethylenedioxythiophene) polystyrene sulfonate has a PEDOT:PSS ratio of 1:2.5.

4. The method of claim 1, wherein said aqueous poly(3,4-ethylenedioxythiophene) polystyrene sulfonate dispersion has a viscosity of 8 to 30 mPa·s.

5. The method of claim 1, wherein forming the coating comprises one or more of dip coating, spin coating, slot-die coating, doctor blade coating, and bar coating.

6. The method of claim 1, further comprising fabricating an electron-transporting sub-layer of the interconnection layer of the multi-junction tandem organic solar cell.

7. The method of claim 1, wherein drying the coating comprises low-temperature anneal at a temperature of approximately 300 degrees Celsius or less.

8. The method of claim 1, wherein said interconnection layer has a dry thickness of less than 20 nm,

9. The method of claim 1, wherein the dried sub-layer has a conductivity of between about 0.1 and about 1.0 millisiemens per centimeter (mS/cm).

10. The method of claim 1, wherein the multi-junction tandem organic solar cell has a PCE (power conversion efficiency) of at least 14.7%.

11. The method of claim 1, further comprising fabricating additional hole-transporting sub-layers of the interconnection layer of the multi-junction tandem organic solar cell.

12. A multi-junction tandem organic solar cell, comprising:
a hole-transporting sub-layer of an interconnection layer of the multi-junction tandem organic solar cell formed by drying a coating of an aqueous poly(3,4-ethylenedioxythiophene) polystyrene sulfonate dispersion liquid formed on a sub-cell surface of a multi-junction tandem organic solar cell.

13. A multi-junction tandem organic solar cell, comprising:
a hole transporting sub-layer of an interconnection layer of the multi-junction tandem organic solar cell comprising poly(3,4-ethylenedioxythiophene) polystyrene sulfonate.

14. The multi-junction tandem organic solar cell of claim 13, wherein said poly(3,4-ethylenedioxythiophene) polystyrene sulfonate has a PEDOT:PSS ratio of 1:2.5.

15. The multi-junction tandem organic solar cell of claim 13, wherein said interconnection layer has a dry thickness of less than 20 nm.

16. The multi-junction tandem organic solar cell of claim 13, further comprising:
a first electrode;
at least two organic photoactive layers; and
a second electrode.

17. The multi-junction tandem organic solar cell of claim 13, comprising:
a first electrode;
a first organic photoactive layer;
an interconnection layer comprising a hole-transporting sub-layer comprising poly(3,4-ethylenedioxythiophene) polystyrene sulfonate and an electron-transporting sub-layer;
a second organic photoactive layer; and
a second electrode.
